(19) United States
(12) Patent Application Publication
(10) Pub. No.: US 2011/0102000 A1
(43) Pub. Date: May 5, 2011

(54) CAPACITIVE MEASURING PROBE AND METHOD FOR PRODUCING A CAPACITIVE MEASURING PROBE

(76) Inventors: Gustav Klett, Moessingen (DE); Markus Niemann, Beckingen (DE)

(21) Appl. No.: 12/936,360

(22) PCT Filed: Dec. 1, 2008
(86) PCT No.: PCT/EP08/66523

§ 371 Date: Dec. 28, 2010

(30) Foreign Application Priority Data
Apr. 10, 2008 (DE) 102008001100.2

(51) Int. Cl. G01R 27/26; B05D 5/12

(52) U.S. Cl. 324/690; 427/58

(57) ABSTRACT

The capacitive measuring probe has the following: two electrodes, a plastic casing which encapsulates the two electrodes, the plastic casing having at least one section made of a conductive plastic, which is electrically connected to one of the two electrodes.

### BACKGROUND INFORMATION

Capacitive measuring probes are described in German Patent Nos. DE 195 11 556 and DE 198 50 291. Capacitive measuring probes are suitable for determining the level of a liquid. The measuring probes have an outer cylindrical, metallic electrode and an inner metallic counter-electrode. The liquid is able to flow in between the two electrodes. Based on the different permittivities of air and the liquid, the capacitance of the measuring probe changes as a function of the liquid level. A suitable evaluation unit estimates the liquid level with the aid of a capacitance measurement.

The use of such capacitive measuring probes is limited to non-corrosive liquids. Liquids such as uric acid change the metallic electrodes, and consequently, their liquid level cannot be determined in a stable manner.

### SUMMARY OF THE INVENTION

The capacitive measuring probe according to the present invention has the following: two electrodes, one plastic casing that encapsulates the two electrodes, the plastic casing having at least one section made of a conductive plastic that is electrically connected to one of the two electrodes.

The method according to the present invention for producing a capacitive measuring probe takes place using the following steps: The forming of two electrodes, the forming of at least one ring made of polyamide on at least one of the two electrodes, the spraying on of a conductive plastic onto one of the two electrodes, adjacent to the polyamide ring, and the spraying on of an insulating plastic for the complete encasing of the areas of the two electrodes that are not covered by the conductive plastic.

The capacitive measuring probe utilizes a coating of the metallic electrodes with a plastic. Improved corrosion resistance is achieved thereby. The plastic may be selected according to the liquid that is to be measured. If suitable plastics are used, one may consequently produce measuring probes even for uric acid, among other things.

The section(s) having conductive plastic increase(s) the sensitivity of the measuring probe.

The production of the capacitive measuring probe, using a closed plastic casing, ensures that no liquid is able to penetrate through joints to a metallic core.

### BRIEF DESCRIPTION OF THE DRAWINGS

FIG. 1 shows a capacitive measuring probe.

FIG. 2 shows a sectional view of the capacitive measuring probe of FIG. 1.

FIG. 3 shows the capacitive measuring probe of FIG. 1 in a different perspective.

FIG. 4 shows the capacitive measuring probe of FIG. 1 without the plastic casing.

FIG. 5 shows a detailed view of FIG. 4.

FIG. 6 shows an additional measuring probe.

FIG. 7 shows a detailed view of the measuring probe of FIG. 6.

### DETAILED DESCRIPTION

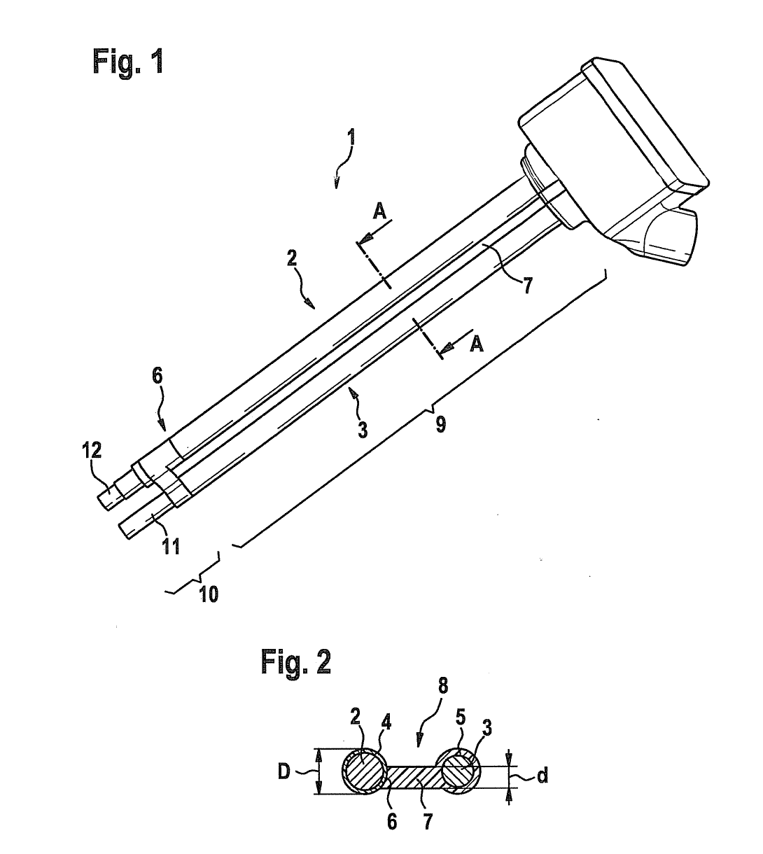

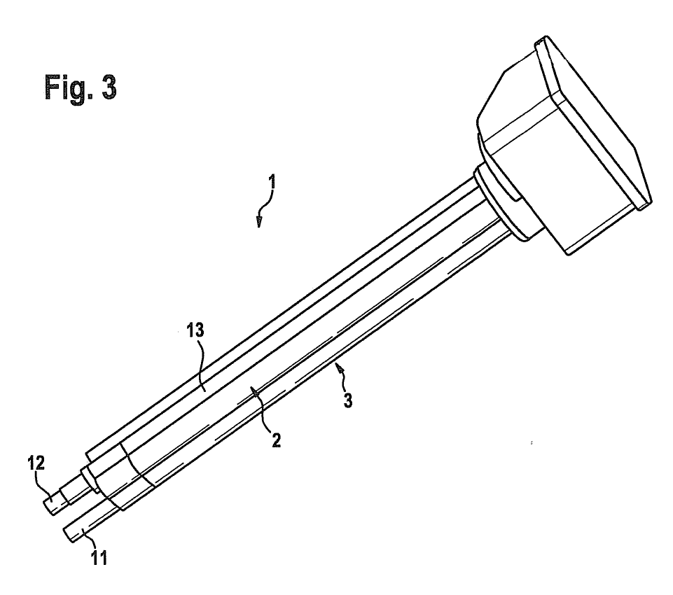

FIG. 1 shows a specific embodiment of a capacitive measuring probe 1. Measuring probe 1 has two electrodes 2, 3. The two electrodes 2, 3 are preferably made of a metal. The two electrodes 2, 3 are surrounded by a closed plastic casing 4, 5. A sectional plane A-A through the two electrodes 2, 3 and their respective plastic casing 4, 5 are shown in FIG. 2. Plastic casing 4 of first electrode 2 is made of a conductive plastic. Plastic casing 5 of second electrode 3 is made of a simple insulating plastic.

The conductive plastic may be produced by the admixture of metal particles or carbon fibers to the plastic granulate during the spraying on. The organic component of the conductive plastic and of the insulating plastic may be the same. This is able to improve the adhesive properties of the two casings to each other at their common joint 6. Consequently, no liquid penetrates the joints. An organic component of the two plastics may be based on polyamides or may be made of polyamides.

The two electrodes 2, 3 are connected mechanically via a crosspiece 7. Crosspiece 7 has a wall thickness d. Diameter D of the two encapsulated electrodes 2, 3 is greater than the wall thickness d. This creates a groove 8 between the two encapsulated electrodes 2, 3.

A liquid is able to flow into groove 8 which, based on its dielectric properties, changes the capacitance between the two electrodes 2, 3. The change in capacitance is recorded quantitatively by an evaluation circuit, and from this the liquid level is ascertained.

Because of its dielectric property, plastic casing 4, 5 has an influence on the measured capacitance. Furthermore, it turns out that the plastic is able to soak up the liquid and gives off the liquid again during drying. This reversible process goes hand-in-hand with a change in the dielectric properties of the plastic.

In the specific embodiment described, the absolute contribution to the capacitance by plastic casing 4, 5 is decreased by the fact that the one plastic casing is developed to be conductive. The dielectric constant is reduced by the conductive inclusions of metal particles or carbon fibers. Capacitive measuring sensor 1 is consequently less sensitive to the changes in the dielectric properties of plastic casing 4, 5.

Beside a liquid level range 9, capacitive measuring probe 1 may have an additional capacitive measuring area 10 for a permittivity measurement of the liquid. This measuring area 10 also has two electrodes 11, 12. The two electrodes 11, 12 in turn are encapsulated in a plastic material. The design corresponds to the design of the electrodes at liquid level range 9. FIG. 3 shows measuring probe 1 in a position rotated about its longitudinal axis compared to the one shown in FIG. 1. A supply line 13 to electrode 12 may now be seen.

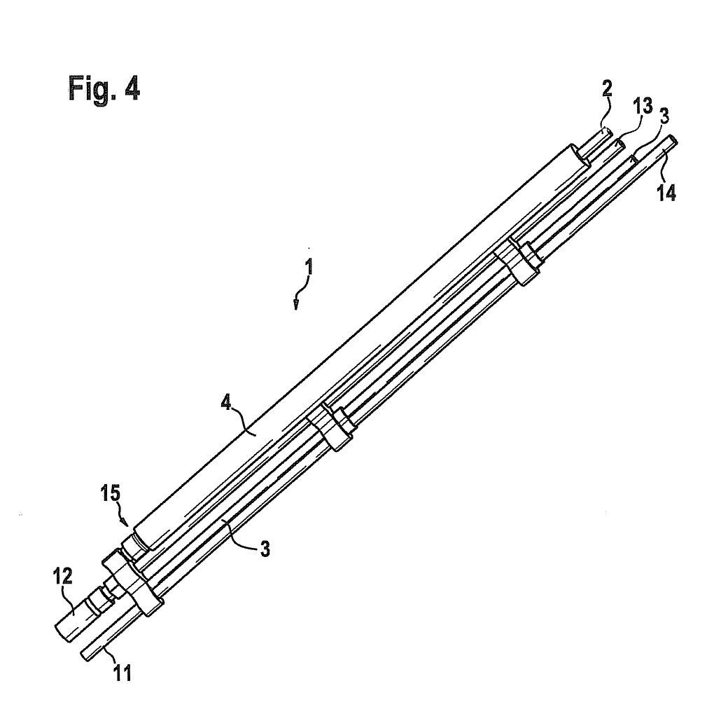

FIG. 4 shows the measuring sensor before insulating plastic 5 is sprayed on. Sprayed-on conductive plastic 4 may have a plurality of ribs 15. These ribs 15 lie at joints 6, at which the two plastics border on each other in finished measuring sensor 1. Ribs 15 increase the surface and are able to improve the adhesion of the insulating plastic to the conductive plastic.

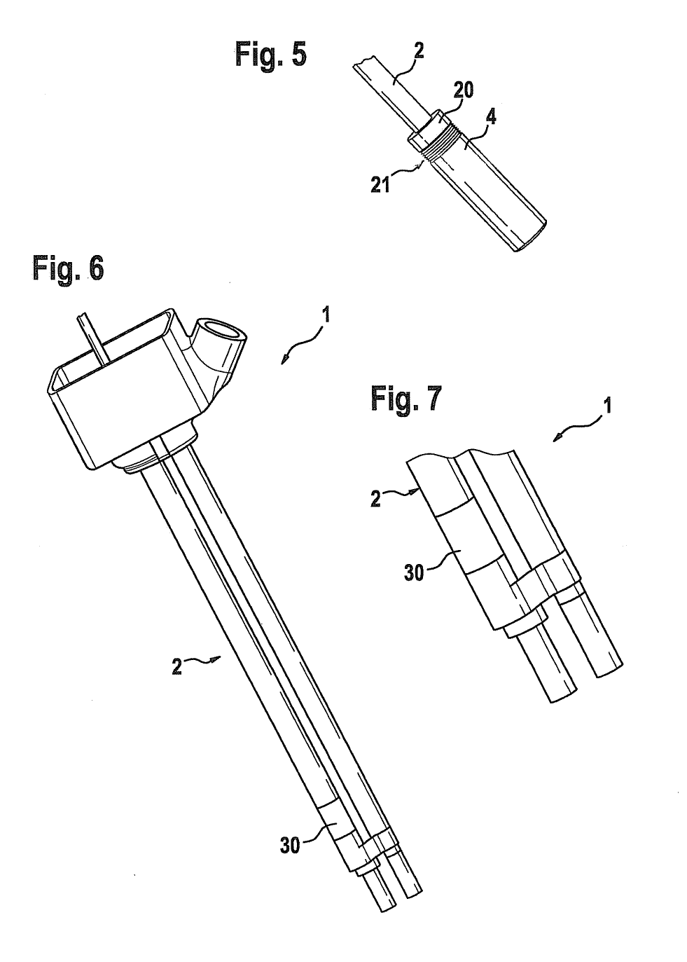

FIG. 5 shows the detail of an additional specific embodiment. A ring 20 is first applied onto electrode 2 or supply line 13 made of metal. Ring 20 may be made of a polyamide or a polypropylene which has particularly high adhesive properties to metal. Ring 20 may be produced from a polyamide or polypropylene which has a greater coefficient of thermal expansion than the plastics that are subsequently sprayed on. Because of this, ring 20 contracts more than the other plastics, and closes joints between conductive plastic 4 and insulating plastic 5.

Conductive plastic 4 is sprayed onto electrode 2 or supply line 13 adjacently and partially onto ring 20. A partial overlapping of conductive plastic 4 with ring 20 ensures a mechanically stable connection.

In the specific embodiment shown, conductive plastic 4 is not sprayed over the entire length of electrodes 2, but only over one section. This section may be in a lower liquid level measuring range 9 by which an even lower liquid level is recorded. The use of conductive plastic 4 in lower liquid level measuring range 9 makes it possible quantitatively to determine a low liquid level using an increased resolution. Thus, it may be reliably ascertained whether liquid has to be replenished or other actions have to be taken.

The other sections of liquid level measuring range 9 may be extrusion-coated with the insulating plastic. The admixture of metal particles or carbon fibers may thereby be omitted. Insulating plastic 5 may be sprayed, in a partially overlapping manner, onto ring 20, adjacent to conductive plastic 4.

FIGS. 6 and 7 show a completely produced measuring probe 1, in which only a section 30 is formed of conductive plastic 4. As shown, section 30 may be applied onto only one electrode 2. On the other hand, a conductive section 30 of conductive plastic may also be provided on both electrodes 2, 3. Conductive section 30 is preferably applied at an area of the liquid level sensor which records a low liquid level.

A ring (not shown) may be sprayed onto the metallic core of electrodes 2, 3. Just as in FIG. 5, the ring may be produced of a polyamide that adheres particularly well to metal. The ring preferably has a plurality of ribs which are later extrusion-coated with the conductive plastic.

1-10. (canceled)

11. A capacitive measuring probe comprising:
two electrodes; and
a plastic casing, which encapsulates the two electrodes, the plastic casing having at least one section made of a conductive plastic, that is electrically connected to one of the two electrodes.

12. The capacitive measuring probe according to claim 11, further comprising at least one ring made of polyamide enclosing one of the electrodes.

13. The capacitive measuring probe according to claim 11, wherein the two electrodes are made of metal.

14. The capacitive measuring probe according to claim 11, further comprising a liquid level sensor.

15. The capacitive measuring probe according to claim 14, wherein the section of conductive plastic is situated in a first area of the liquid level sensor which corresponds to a low liquid level, and a second area of the liquid level sensor, that corresponds to a liquid level that is not low, is surrounded by an insulating plastic.

16. The capacitive measuring probe according to claim 11, wherein a longitudinal groove running alongside the electrodes is inserted into the casing between the two electrodes.

17. The capacitive measuring probe according to claim 16, wherein the probe has a liquid level measuring range and the longitudinal groove extends substantially over the entire liquid level measuring range.

18. A method for producing a capacitive measuring probe, comprising:
forming two electrodes;
forming at least one ring from a first plastic on at least one of the two electrodes;
spraying a conductive plastic on one of the two electrodes adjacent to the ring; and
spraying an insulating plastic for a complete encapsulation of areas of the two electrodes that are not covered by the conductive plastic.

19. The method according to claim 18, wherein the at least one ring is extrusion-coated partially by the conductive plastic and partially by the insulating plastic.

20. The method according to claim 18, wherein at least one of the insulating plastic and the conductive plastic are produced from polyamide or polypropylene.
